(19) United States
(12) Patent Application Publication
(10) Pub. No.: US 2015/0270323 A1
(43) Pub. Date: Sep. 24, 2015

(54) ORGANIC LIGHT-EMITTING DISPLAY APPARATUS AND MANUFACTURING METHOD THEREOF

(71) Applicant: Samsung Display Co., Ltd., Yongin-City (KR)

(72) Inventors: Seung-Yeon Cho, Yongin-City (KR); Hwa-Jeong Kim, Yongin-City (KR)

(21) Appl. No.: 14/304,082

(22) Filed: Jun. 13, 2014

(30) Foreign Application Priority Data
Mar. 24, 2014 (KR) 10-2014-0034134

(51) Int. Cl. H01L 27/32; H01L 51/56

(52) U.S. Cl. CPC H01L 27/3272; H01L 27/3262; H01L 51/56; H01L 27/3276; H01L 2227/323

(57) ABSTRACT

A display apparatus includes a first conductive portion and a second conductive portion that are connected to each other via a contact hole which is formed through an insulation layer disposed between the first and second conductive portions. The display apparatus further includes a shield layer that covers at least one edge of the first conductive portion.

### RELATED APPLICATION

This application claims the benefit of Korean Patent Application No. 10-2014-0034134, filed on Mar. 24, 2014, in the Korean Intellectual Property Office, the disclosure of which is incorporated herein in its entirety by reference.

### BACKGROUND

1. Field

One or more embodiments of the present invention relate to an organic light-emitting display apparatus and a manufacturing method thereof.

2. Description of the Related Art

In general, an organic light-emitting display apparatus is a display apparatus including thin film transistors and organic light-emitting diodes (OLEDs), in which holes and electrons injected into anodes and cathodes of the OLEDs recombine in an emission layer between the anodes and cathodes and emit light to thus display an image.

### SUMMARY

One or more embodiments of the present invention include an organic light-emitting display apparatus and a manufacturing method thereof.

Additional aspects will be set forth in part in the description which follows and, in part, will be apparent from the description, or may be learned by practice of the presented embodiments.

One aspect of the invention provides an organic light-emitting display apparatus comprising: a substrate comprising a major surface; and a display unit formed over the substrate, wherein the display unit comprises: a first conductive portion, a second conductive portion, and an insulation layer disposed between the first and second conductive portions, the first and second conductive portions connected to each other via a contact hole formed in the insulation layer; and a shield layer formed between the first and second conductive portions so as to overlap at least one edge of the first conductive portion when viewed in a direction perpendicular to the major surface.

In the foregoing apparatus, each of the first and second conductive portions may comprise one selected from the group consisting of an active layer of a thin film transistor, an electrode, a conductive line, a conductive pad, a conductive trace, and a conductive track. The shield layer may further overlap a portion of the first conductive portion next to the at least one edge. The shield layer may be disposed at a side of the contact hole. The shield layer may surround the contact hole when viewed in the direction. A material of the shield layer may comprise any one of metal and polymer. The shield layer may be spaced from the first conductive portion so as to not contact the first conductive portion. The display unit may comprise a thin film transistor (TFT) that comprises an active layer, a gate electrode, a source electrode, and a drain electrode which are formed over the substrate, and wherein the first conductive portion is the active layer, and the second conductive portions is one of the source and drain electrodes. The shield layer and the gate electrode may be formed on the same level by using the same material.

Another aspect of the invention provides a method of manufacturing an organic light-emitting display apparatus, the method comprising: providing a substrate; and forming a display unit over the substrate, wherein the forming of the display unit comprises: forming a first conductive portion over the substrate; forming an insulation layer and a shield layer over the first conductive portion, wherein the shield layer is disposed in the insulation layer and overlaps at least one edge of the first conductive portion; forming a contact hole through the insulation layer to expose a portion of the first conductive portions, the exposed portion does not include any edges of the first conductive portion; and forming a second conductive portion that is connected to the first conductive portion via the contact hole.

In the foregoing method, forming the insulation layer and the shield layer may comprise: forming a first sub-layer of the insulation layer; forming the shield layer over the first sub-layer; and forming a second sub-layer of the insulation layer, wherein the shield layer is disposed between the first and second sub-layers. The shield layer may be disposed at a side of the contact hole. The shield layer may surround the contact hole. A material of the shield layer may comprise any one of metal and polymer. The shield layer may be spaced from the first conductive portion. The display unit may comprise a thin film transistor (TFT) that comprises an active layer, a gate electrode, a source electrode, and a drain electrode which are formed over the substrate, and wherein the first conductive portion is the active layer, and the second conductive portion is one of the source and drain electrodes. The shield layer and the gate electrode may be formed on the same level by using the same material.

A further aspect of the invention provides a method of making a flat panel display apparatus, the method comprising: providing a substrate comprising a major surface; and forming an array of display pixels over the substrate, wherein forming of the array of display pixels comprises: forming a first conductive portion over the substrate; forming a first insulation layer over the first conductive portion; forming a shield over the first insulation layer, the shield overlapping at least one edge of the first conductive portion when viewing in a direction perpendicular to the major surface; forming a second insulation layer over the first insulation layer, wherein the shield is disposed between the first and second insulation layers; forming a contact hole through the first and second insulation layers at a position next to the shield to expose a portion of the first conductive portion, wherein the contact hole does not expose the at least one edge overlapping the shield, forming a second conductive portion connected to the first conductive portion through the contact hole.

In the foregoing method, the first conductive portion may be an active layer of a thin film transistor, wherein the second conductive portion may be an electrode, wherein the shield comprises metal or polymer. Forming the contact hole may comprise etching the first and second insulation layers using an etchant, wherein the shield inhibits the etchant from reaching the at least one edge while etching the first and second insulation layers, wherein the shield may be formed of a material which is substantially non-etchable with the etchant.

According to one or more embodiments of the present invention, an organic light-emitting display apparatus includes a substrate; and a display unit formed on the substrate, the display unit includes a first wiring and a second wiring disposed on different layers and connected to each other via a contact hole formed in an insulating layer which is formed between the first and second wirings; and a shield layer formed between the first and second wirings so as to cover outer areas of ends of any one of the first and second wiring that is formed before the contact hole.

The shield layer may be formed to overlap a portion of an inner area of the ends.

The shield layer and the contact hole may be formed after the first wiring is formed and before the second wiring is formed, the shield layer may cover outer areas of ends of the first wiring, and the contact hole may be formed by etching the insulating layer such that inner areas of the ends of the first wiring that is not covered by the shield layer is exposed.

The shield layer may be formed at a side of the contact hole.

The shield layer may surround the contact hole.

A material of the shield layer may include any one of metal and polymer.

The shield layer may be separated so as to not contact other wirings.

The display unit may include a thin film transistor (TFT) that includes an active layer, a gate electrode, a source electrode, and a drain electrode which are formed on different levels on the substrate. The first electrode may correspond to the active layer, and the second electrode may correspond to the source and drain electrodes.

The shield layer and the gate electrode may be formed on the same level by using the same material.

According to one or more embodiments of the present invention, a method for manufacturing an organic light-emitting display apparatus includes preparing a substrate; and forming a display unit on the substrate. The forming of the display unit includes forming a first wiring on the substrate; forming an insulating layer on the first wiring; forming a shield layer, which covers outer areas of ends of the first wiring, on the insulating layer; forming a contact hole, which is connected to inner areas of the ends of the first wiring, on the insulating layer; and forming a second wiring that is connected to the first wiring via the contact hole.

The shield layer may be formed to overlap a portion of the inner area of the ends.

The shield layer may be formed at a side of the contact hole.

The shield layer may surround the contact hole.

A material of the shield layer may include any one of metal and polymer.

The shield layer may be separated from other wirings.

The display unit may include a thin film transistor (TFT) that includes an active layer, a gate electrode, a source electrode, and a drain electrode which are formed on different levels on the substrate. The first electrode may correspond to the active layer, and the second electrode may correspond to the source and drain electrodes.

The shield layer and the gate electrode may be formed on the same level by using the same material.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of an organic light-emitting display apparatus according to an embodiment of the present invention;

FIG. 2 is an enlarged sectional view of a display unit of the organic light-emitting display apparatus of FIG. 1;

FIG. 3A is a plan view of a structure surrounding a contact hole of FIG. 2;

FIG. 3B is a plan view of a modified example of FIG. 3A; and

FIGS. 4A to 4F is a view of a method of manufacturing the display unit of FIG. 2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

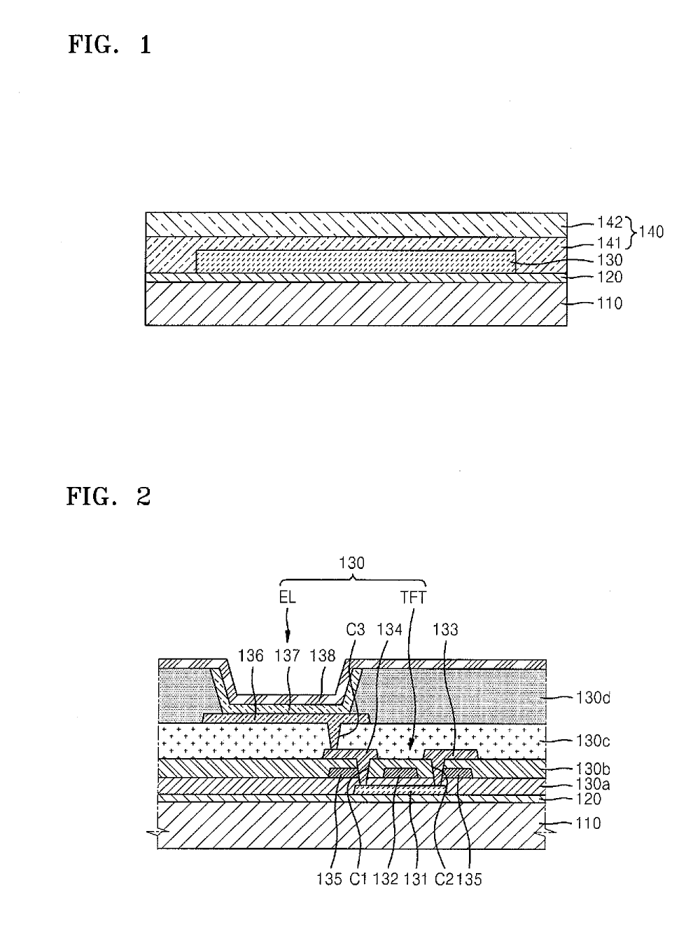

FIG. 1 is a cross-sectional view of an organic light-emitting display apparatus according to an embodiment of the present invention.

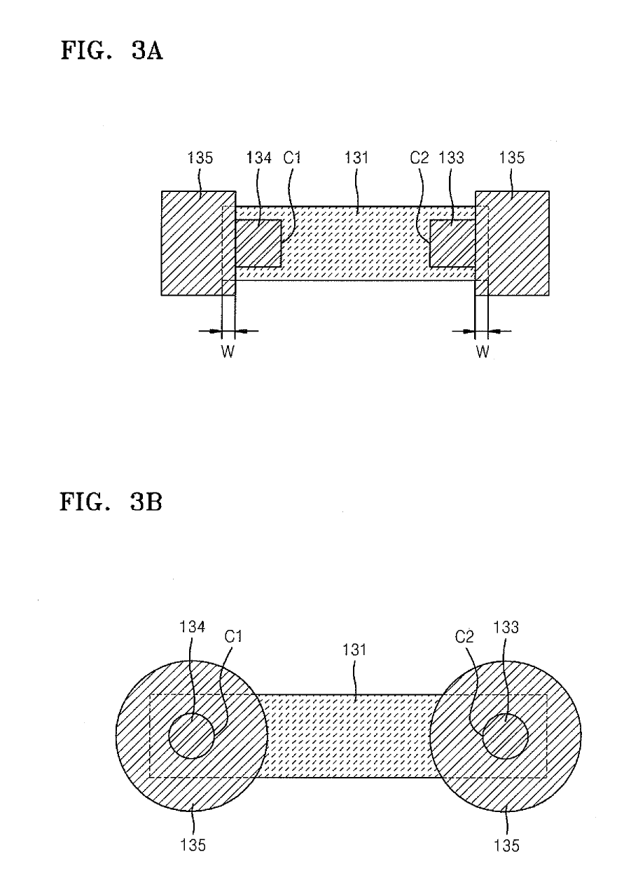

As illustrated in FIG. 1, the organic light-emitting display apparatus according to the present embodiment has a structure that is formed by stacking a flexible substrate 110 formed of a polyimide material, a barrier layer 120, a display unit 130 including a thin film transistor (TFT) TFT (refer to FIG. 2) and an organic light-emitting diode (OLED) EL (refer to FIG. 2), and a thin film encapsulating layer 140 in which an organic layer 141 and an inorganic layer 142 are alternately stacked. The organic light-emitting display apparatus may become flexible by using the flexible substrate 110 and thin film encapsulating layer 140 to encapsulate the display unit 130. In other embodiments, a thick and hard glass substrate may be used.

In embodiments, the flexible substrate 110 may be formed of a heat-resisting polyimide material having a glass transition temperature of about 500° C. or above. The flexible substrate 110 functions as a flexible thin film substrate that replaces a general glass substrate.

The barrier layer 120 is a moisture-proof layer that prevents external moisture penetration. The barrier layer 120 may be formed of, for example, a multi-layer of SiO/SiN, which is formed by stacking multi-layers of SiO and SiN and has a water vapor transmission rate of about 10⁻³ g/m²·day or less.

The thin film encapsulating layer 140, which is formed on the display unit 130, covers and thus protects the display unit 130, and has a structure in which the organic layer 141 and the inorganic layer 142 are alternately stacked.

In embodiments, the display unit 130 may have a structure illustrated in FIG. 2. As illustrated in FIG. 2, the display unit 130 includes the thin film transistor TFT and the OLED EL, and a drain electrode 134 of the thin film transistor TFT and a pixel electrode 136 of the OLED EL are connected to each other.

First, the thin film transistor TFT will be described in detail. A semiconductor active layer 131 is formed on the barrier layer 120 that is on the substrate 110. In embodiments, the semiconductor active layer 131 may be formed by using oxide semiconductor. For example, the oxide semiconductor may include an oxide of a material selected from a group 12 metal, a group 13 metal, a group 14 metal, and combinations thereof. Examples of the group 12 metal, the group 13 metal, and the group 14 metal include zinc (Zn), indium (In), tin (Sn), cadmium (Cd), germanium (Ge), and hafnium (Hf). For example, the semiconductor active layer 131 may include G-I-Z-O[(In₂O₃)a(Ga₂O₃)b(ZnO)c] (where a, b, and c are real numbers that respectively satisfy a≧0, b≧0, and c>0). In other embodiments, the active layer may be formed of a polycrystalline silicon doped with impurities.

A first insulating layer 130a is disposed on the semiconductor active layer 131, and a gate electrode 132 is formed on the first insulating layer 130a. Also, a shield layer 135 is formed on the same layer as the gate electrode 132. When etching to form contact holes C1 and C2, the shield layer 135 can reduce or minimize the risk of over-etching to beyond the end portions of the semiconductor active layer 131. The function of the shield layer 135 will be described again below. A second insulating layer 130b is disposed on the gate electrode 132, and a source electrode 133 and the drain electrode 134 are formed on the second insulating layer 130b, the source and drain electrodes 133 and 134 are connected to the semiconductor active layer 131 via the contact holes C1 and C2 that penetrate through the first and second insulating layers 130a and 130b.

A third insulating layer 130c is formed on the source and drain electrodes 133 and 134, and the pixel electrode 136 of the OLED EL is formed on the third insulating layer 130c. The drain electrode 134 and the pixel electrode 136 are connected to each other via a contact hole C3 that is formed in the third insulating layer 130c.

A pixel defining layer (PDL) 130d, which defines pixel areas, is formed on the pixel electrode 136, and an emission layer 137 is formed in the pixel areas defined by the PDL 130d. A hole injection layer (HIL), a hole transport layer (HTL), an electron transport layer (ETL), and an electron injection layer (EIL) may be stacked near the emission layer 137.

In the emission layer 137, each pixel may be divided into different colors so that pixels that emit red, green, and blue light may form a single unit pixel. Alternatively, a common emission layer may be formed over the entire pixel area regardless of locations of pixels. In this case, the emission layer may be formed by, for example, vertically stacking or combining layers that include emission materials that emit red, green, and blue light. If white light may be emitted, combinations of other colors may be possible. A color conversion layer that converts white light into a predetermined color light, or a color filter may be further included.

An opposite electrode 138 is formed on the emission layer 137.

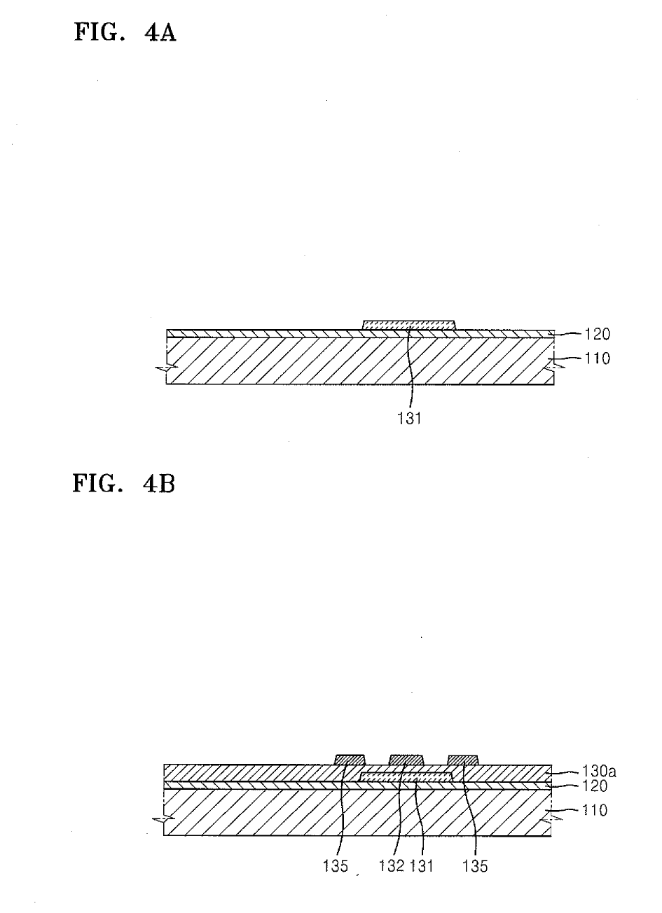

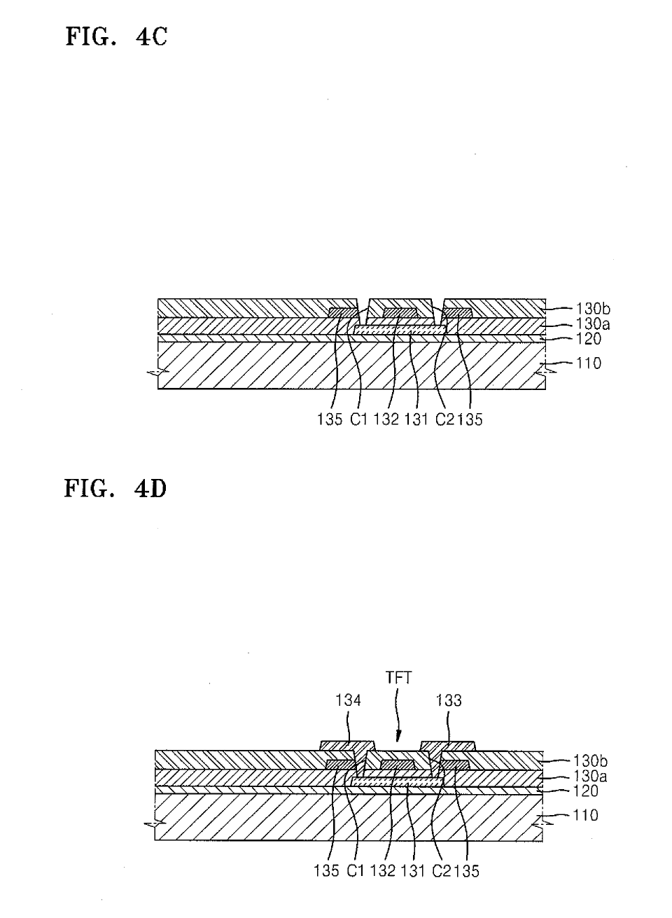

Hereinafter, the structure and the function of the shield layer or shield portion 135 will be described in detail. The shield layer 135 may have a structure as shown in FIG. 3A. As illustrated in FIG. 3A, the shield layer 135 is formed on the first insulating layer 130a such that the end portion of the semiconductor active layer 131 including edges are covered. As shown in FIG. 3A, each of the shield layers 135 is disposed such that the shield layer 135 at least slightly overlaps the corresponding end portion of the semiconductor active layer 131 (by “w” as marked in FIG. 3A). Then, in a plan view shown in FIG. 3A, each of the shield layer 135 covers the corresponding end portion of the semiconductor active layer 131, and thus functions as a barrier that prevents or minimizes over-etching when forming the contact holes C1 and C2. If the shield layer 135 is not provided, an etchant may over-etch and flow beyond the end portion of the semiconductor active layer 131 when etching to form the contact holes C1 and C2, thereby forming gaps or slits in the first insulating layer 130a as well as the barrier layer 120 and the substrate 110 that are provided under the semiconductor active layer 131. Since the gaps or slits may be a starting point of cracks in the future, the gaps or slits may be a cause of a product failure. However, since the shield layer 135 is provided as in the present embodiment, and the end portions of the semiconductor active layer 131 are protected from being over-etched when forming the contact holes C1 and C2, it is possible to sufficiently reduce or minimize the risk of cracks. The shield layer 135 may be formed by using a metal material such as aluminum, molybdenum, silver, and the like, or a polymer material such as polyimide. The shield layer 135 is separated from other conductive portions so as to not contact the other conductive portions. In alternative embodiments, the shield layer 135 may be formed such that edges of the shield layer and active layer exactly match if such configuration can sufficiently inhibit the etchant from reaching the edge of the active layer.

As illustrated in FIG. 3A, the shield layers 135 may respectively be formed at one side of the contact holes C1 and C2, to cover each of the opposite end portions of the semiconductor active layer 131. Alternatively, as illustrated in FIG. 3B, the shield layers 135 may respectively be formed to surround the contact holes C1 and C2.

The organic light-emitting display apparatus, which includes the display unit 130 having the above-described structure, may be manufactured according to a process described below.

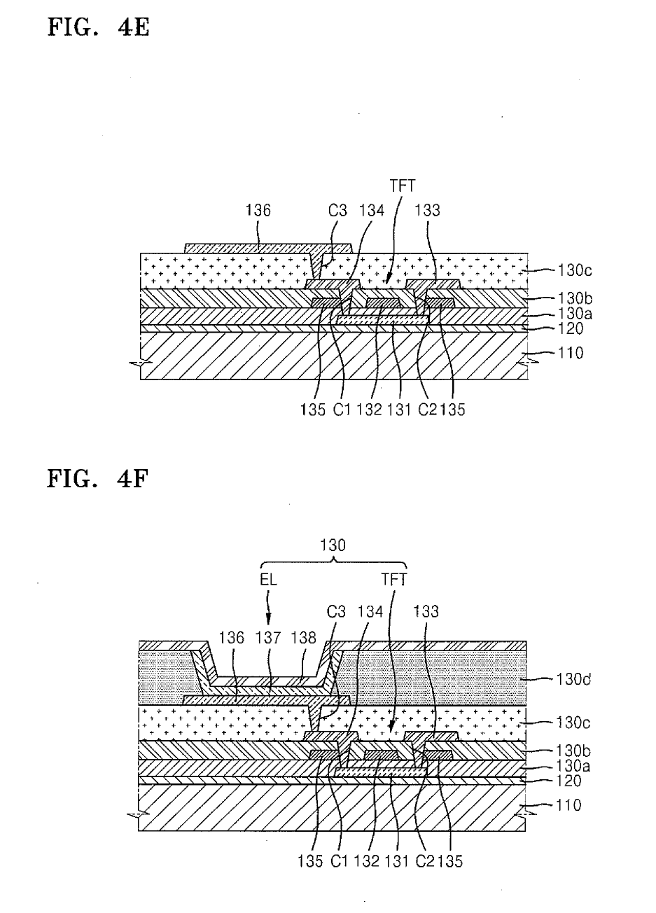

First, as illustrated in FIG. 4A, the barrier layer 120 is formed on the substrate 110, and then, the semiconductor active layer 131 of the thin film transistor TFT is formed on the barrier layer 120.

Then, as illustrated in FIG. 4B, the first insulating layer 130a is formed on the semiconductor active layer 131, and then, the gate electrode 132 and the shield layer 135 are formed on the first insulating layer 130a. The shield layer 135 and the gate electrode 132 may be formed according to separate patterning processes, or may be simultaneously patterned on the same layer by using the same material. As illustrated in FIG. 3A or 3B, the shield layer 135 is disposed such that it covers the end portion or the peripheral area of the semiconductor active layer 131.

As illustrated in FIG. 4C, the second insulating layer 130b is formed, and then, the contact holes C1 and C2 that is connected to the semiconductor active layer 131 are formed by etching. In this case, since the shield layer 135 is preventing an etchant from etching to the end portion and the edge of the semiconductor active layer 131, formation of a gap or slit, which may be a starting point of cracks in a product, is inhibited or minimized.

As illustrated in FIG. 4D, the source and drain electrodes 133 and 134 are formed and connected to the semiconductor active layer 131 via the contact holes C1 and C2.

As illustrated in FIG. 4E, the third insulating layer 130c and the contact hole C3 are formed, and the pixel electrode 136 of the OLED EL is connected to the drain electrode 134 via the contact hole C3.

As illustrated in FIG. 4F, the PDL 130d, the emission layer 137, and the opposite electrode 138 are sequentially formed to thus complete the display unit 130. Then, by forming the organic layer 141 and the thin film encapsulating layer 140 of the inorganic layer 142 on the display unit 130, the organic light-emitting display apparatus of FIG. 1 is complete.

As described above, according to the one or more of the above embodiments of the present invention, in the organic light-emitting display apparatus that is manufactured according to the above-described process, since the risk of formation of gaps that may be starting points of cracks in a product is sufficiently reduced or minimized, lifespan and reliability of the product may be greatly increased.

According to the above-described embodiments of the present invention, the shield layer 135 is applied around the contact holes C1 and C2 that connect the semiconductor active layer 131 and the source and drain electrodes 133 and 134. However, the embodiments of the present invention are not limited thereto. The shield layer 135 may be applied around the contact hole C3 between the pixel electrode 136 and the drain electrode 134 to thus inhibit or minimize over-etching. In embodiments, if there are a first conductive portion and a second conductive portion in the display unit 130, which are disposed in different layers having an insulating layer therebetween and are connected via a contact hole, the shield layer 135 may be provided between the first and second conductive portions as described above to thus solve a problem of gaps that are formed due to over-etching. In embodiments, the first and second conductive portions may include any electrically conductive features, such as, an active layer of a thin film transistor, an electrode, a conductive line, a conductive pad, a conductive trace, and a conductive track.

Further, in the illustrated embodiments, the shield layer structure is applied to organic light emitting display devices. However, the present invention is not limited thereto. Such shield layer structure may be applied to any other type of display device which includes two conductive portions connected via a contact hole.

Therefore, according to the organic light-emitting display apparatus having the above-described structure and a method of manufacturing the organic light-emitting display apparatus, formation of cracks may be reduced or minimized, and lifespan and reliability of the product may be greatly increased.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. An organic light-emitting display apparatus comprising:
a substrate comprising a major surface; and
a display unit formed over the substrate,
wherein the display unit comprises:
a first conductive portion, a second conductive portion, and an insulation layer disposed between the first and second conductive portions, the first and second conductive portions connected to each other via a contact hole formed in the insulation layer; and
a shield layer formed between the first and second conductive portions so as to overlap at least one edge of the first conductive portion when viewed in a direction perpendicular to the major surface.

2. The apparatus of claim 1, wherein each of the first and second conductive portions comprises one selected from the group consisting of an active layer of a thin film transistor, an electrode, a conductive line, a conductive pad, a conductive trace, and a conductive track.

3. The apparatus of claim 1, wherein the shield layer further overlaps a portion of the first conductive portion next to the at least one edge.

4. The apparatus of claim 1, wherein the shield layer is disposed at a side of the contact hole.

5. The apparatus of claim 1, wherein the shield layer surrounds the contact hole when viewed in the direction.

6. The apparatus of claim 1, wherein a material of the shield layer comprises any one of metal and polymer.

7. The apparatus of claim 1, wherein the shield layer is spaced from the first conductive portion so as to not contact the first conductive portion.

8. The apparatus of claim 1, wherein the display unit comprises a thin film transistor (TFT) that comprises an active layer, a gate electrode, a source electrode, and a drain electrode which are formed over the substrate, and
wherein the first conductive portion is the active layer, and the second conductive portions is one of the source and drain electrodes.

9. The apparatus of claim 8, wherein the shield layer and the gate electrode are formed on the same level by using the same material.

10. A method of manufacturing an organic light-emitting display apparatus, the method comprising:
providing a substrate; and
forming a display unit over the substrate,
wherein the forming the display unit comprises:
forming a first conductive portion over the substrate;
forming an insulation layer and a shield layer over the first conductive portion, wherein the shield layer is disposed in the insulation layer and overlaps at least one edge of the first conductive portion;
forming a contact hole through the insulation layer to expose a portion of the first conductive portions, the exposed portion does not include any edges of the first conductive portion; and
forming a second conductive portion that is connected to the first conductive portion via the contact hole.

11. The method of claim 10, wherein forming the insulation layer and the shield layer comprises:
forming a first sub-layer of the insulation layer;
forming the shield layer over the first sub-layer; and
forming a second sub-layer of the insulation layer, wherein the shield layer is disposed between the first and second sub-layers.

12. The method of claim 10, wherein the shield layer is disposed at a side of the contact hole.

13. The method of claim 10, wherein the shield layer surrounds the contact hole.

14. The method of claim 10, wherein a material of the shield layer comprises any one of metal and polymer.

15. The method of claim 10, wherein the shield layer is spaced from the first conductive portion.

16. The method of claim 10, wherein the display unit comprises a thin film transistor (TFT) that comprises an active layer, a gate electrode, a source electrode, and a drain electrode which are formed over the substrate, and
wherein the first conductive portion is the active layer, and the second conductive portion is one of the source and drain electrodes.

17. The method of claim 16, wherein the shield layer and the gate electrode are formed on the same level by using the same material.

18. A method of making a flat panel display apparatus, the method comprising:
providing a substrate comprising a major surface; and
forming an array of display pixels over the substrate,
wherein forming of the array of display pixels comprises:
forming a first conductive portion over the substrate;
forming a first insulation layer over the first conductive portion;
forming a shield over the first insulation layer, the shield overlapping at least one edge of the first conductive portion when viewing in a direction perpendicular to the major surface;
forming a second insulation layer over the first insulation layer, wherein the shield is disposed between the first and second insulation layers;
forming a contact hole through the first and second insulation layers at a position next to the shield to expose a portion of the first conductive portion, wherein the contact hole does not expose the at least one edge overlapping the shield,
forming a second conductive portion connected to the first conductive portion through the contact hole.

19. The method of claim 18, wherein the first conductive portion is an active layer of a thin film transistor, wherein the second conductive portion comprises an electrode, wherein the shield comprises metal or polymer.

20. The method of claim 18, wherein forming the contact hole comprises etching the first and second insulation layers using an etchant, wherein the shield inhibits the etchant from reaching the at least one edge while etching the first and second insulation layers,
wherein the shield is formed of a material which is substantially non-etchable with the etchant.
